(19) United States
(12) Patent Application Publication
(10) Pub. No.: US 2025/0149467 A1
(43) Pub. Date: May 8, 2025

(54) SEMICONDUCTOR DEVICE AND METHOD OF MANUFACTURING THE SAME

(71) Applicant: Samsung Electronics Co., Ltd., Suwon-si (KR)

(72) Inventors: Juil Choi, Suwon-si (KR); Jongho Park, Suwon-si (KR); Chanwook Park, Suwon-si (KR); Hyungjun Park, Suwon-si (KR); Taeoh Ha, Suwon-si (KR); Hongseo Heo, Suwon-si (KR)

(21) Appl. No.: 18/917,246

(22) Filed: Oct. 16, 2024

(30) Foreign Application Priority Data
Nov. 3, 2023 (KR) 10-2023-0150781
Jan. 4, 2024 (KR) 10-2024-0001384

(51) Int. Cl. H01L 23/00; H01L 23/16; H01L 23/538; H01L 25/00; H01L 25/065; H01L 25/18; H10B 80/00

(52) U.S. Cl. CPC H01L 23/562; H01L 23/16; H01L 23/5383; H01L 23/5389; H01L 24/08; H01L 24/80; H01L 25/0657; H01L 25/18; H01L 25/50; H10B 80/00; H01L 2224/08146; H01L 2224/80006; H01L 2224/80895; H01L 2224/80896; H01L 2225/06541; H01L 2225/06568; H01L 2924/1431; H01L 2924/146; H01L 2924/3511

(57) ABSTRACT

A semiconductor package includes a first die structure including a support substrate having a cavity, a first semiconductor chip in the cavity, and a first gap filling layer that fills a gap between an inner wall of the cavity and the first semiconductor chip; and a second die structure on the first die structure, the second die structure including a second semiconductor chip and a second gap filling layer surrounding an outer side surface of the second semiconductor chip. The first semiconductor chip includes a first backside insulating layer with second bonding pads. The second semiconductor chip includes a second front insulating layer with third bonding pads. The second bonding pads and the third bonding pads are directly bonded to each other.

### PRIORITY STATEMENT

This application claims priority under 35 U.S.C. § 119 to Korean Patent Application Nos. 10-2023-0150781, filed on Nov. 3, 2023, and 10-2024-0001384, filed on Jan. 4, 2024, in the Korean Intellectual Property Office (KIPO), the contents of which are herein incorporated by reference in their entirety.

### BACKGROUND

Example embodiments relate to a semiconductor device and a method of manufacturing the semiconductor device. More particularly, example embodiments relate to a semiconductor device including a plurality of stacked semiconductor chips and a method of manufacturing the same.

In manufacturing a 3D IC package, individually separated first semiconductor chips may be placed on a carrier substrate, a gap-fill oxide layer may be formed to cover the first semiconductor chips, and a second semiconductor chip may be bonded on the first semiconductor chip by a die-to-wafer bonding process. Accordingly, warpage of the entire wafer may be determined depending on the layer quality of the gap-fill oxide layer. In order to control the warpage, the gap fill oxide layer may be changed, and accordingly, insulating properties and gap fill characteristics of the gap fill oxide layer may deteriorate due to changes in layer quality.

### SUMMARY

Example embodiments provide a semiconductor device capable of preventing warpage and having improved bonding quality.

Example embodiments provide a method of manufacturing the semiconductor device.

According to example embodiments, a semiconductor device includes a first die structure including a support substrate having a cavity therein, a first semiconductor chip in the cavity, and a first gap filling layer that fills a gap between an inner wall of the cavity and the first semiconductor chip; and a second die structure on the first die structure, the second die structure including a second semiconductor chip and a second gap filling layer surrounding an outer side surface of the second semiconductor chip, the second semiconductor chip on the first semiconductor chip and electrically connected to the first semiconductor chip. The first semiconductor chip includes a first substrate, a first front insulating layer on a first surface of the first substrate with first bonding pads therein or thereon, and a first backside insulating layer on a second surface of the first substrate opposite the first surface of the first substrate with second bonding pads therein or thereon. The second semiconductor chip includes a second substrate and a second front insulating layer on a first surface of the second substrate with third bonding pads therein or thereon. The second bonding pads are directly bonded to the third bonding pads.

According to example embodiments, a semiconductor device includes a first die structure including a support substrate including a body having a first surface and a second surface opposite the first surface and having a cavity that extends from the first surface to the second surface with the body surrounding the cavity, a first chiplet die in the cavity, and a first gap filling layer that fills a gap between an inner wall of the cavity and the first chiplet die; and a second die structure on the first die structure, the second die structure including a second chiplet die on the first chiplet die and electrically connected to the first chiplet die, and a second gap filling layer surrounding an outer side surface of the second chiplet die. The first chiplet die includes a first substrate, a plurality of through electrodes extending at least partially through the first substrate, first bonding pads on a first surface of the first substrate and electrically connected to the plurality of through electrodes, second bonding pads on a second surface of the first substrate opposite the first surface and electrically connected to the plurality of through electrodes. The second chiplet die includes a second substrate and third bonding pads on a first surface of the second substrate. The first bonding pads are directly bonded to the second bonding pad.

According to example embodiments, a semiconductor device includes a first die structure including a support substrate having a cavity, a first semiconductor chip in the cavity, and a first gap filling layer that fills a gap between an inner wall of the cavity and the first semiconductor chip; and a second die structure stacked on the first die structure, the second die structure including a second semiconductor chip on the first semiconductor chip and electrically connected to the first semiconductor chip, and a second gap filling layer surrounding the second semiconductor chip. An outer side surface of the second gap filling layer is coplanar with an outer side surface of the support substrate.

According to example embodiments, in a method of manufacturing a semiconductor device, a support substrate having a first surface and a second surface opposite the first surface is provided. A recess is formed in the support substrate to have a predetermined depth from the first surface. A first semiconductor chip is positioned within the recess. A first gap filling layer is formed to fill a gap between an outer side surface of the first semiconductor chip and an inner surface of the recess. A second semiconductor chip is bonded on the first semiconductor chip. A second gap filling layer is formed on the glass substrate to surround an outer side surface of the second semiconductor chip. The second surface of the support substrate is partially removed to expose the first semiconductor chip.

According to example embodiments, a semiconductor device may include a first die structure and a second die structure stacked on the first die structure. The first die structure may include a support substrate having a cavity therein, a first semiconductor chip disposed in the cavity, and a first gap filling layer that fills a gap between an inner wall of the cavity and the first semiconductor chip. The second die structure may include a second semiconductor chip electrically connected to the first semiconductor chip and a second gap filling layer surrounding the second semiconductor chip.

The support substrate may have a first coefficient of thermal expansion, and the first gap filling layer may have a second coefficient of thermal expansion that is greater than the first coefficient of thermal expansion. Since the support substrate containing glass has a more dense composition than the first gap filling layer, the support substrate may have excellent mechanical strength and thermal resistance characteristics according to temperature changes compared to the first gap filling layer. Accordingly, a ratio occupied by the support substrate may be adjusted to reduce or control warpage of the first die structure.

### BRIEF DESCRIPTION OF THE DRAWINGS

Example embodiments will be more clearly understood from the following detailed description taken in conjunction with the accompanying drawings. FIGS. 1 to 31 represent non-limiting, example embodiments as described herein.

FIG. 1 is a cross-sectional view illustrating a semiconductor package in accordance with example embodiments.

FIG. 2 is an enlarged cross-sectional view illustrating portion ‘A’ in FIG. 1.

FIG. 3 is a plan view illustrating a lower die structure in FIG. 1.

FIG. 4 is a plan view illustrating an upper die structure in FIG. 1.

FIGS. 5 to 25 are views illustrating a method of manufacturing a semiconductor package in accordance with example embodiments.

FIG. 26 is a cross-sectional view illustrating a semiconductor package in accordance with example embodiments.

FIGS. 27 to 29 are cross-sectional views illustrating a method of manufacturing a semiconductor package in accordance with example embodiments.

FIG. 30 is a cross-sectional view illustrating a semiconductor package in accordance with example embodiments.

FIG. 31 is a cross-sectional view illustrating a semiconductor package in accordance with example embodiments.

### DETAILED DESCRIPTION

Hereinafter, example embodiments will be explained in detail with reference to the accompanying drawings.

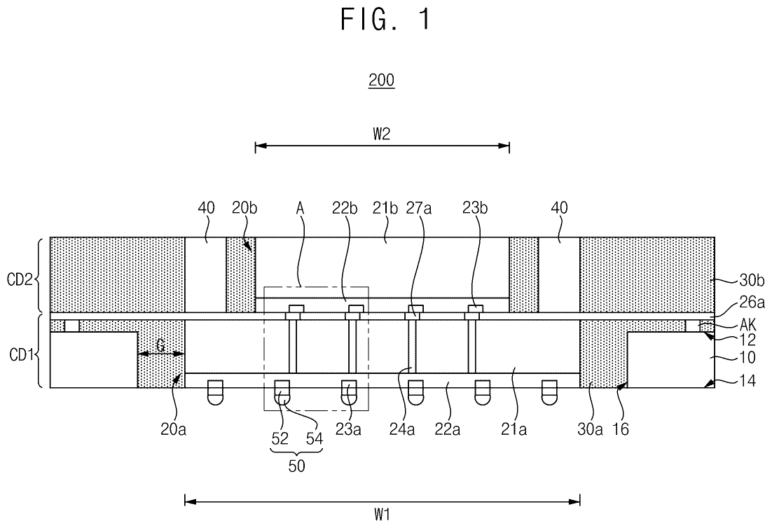

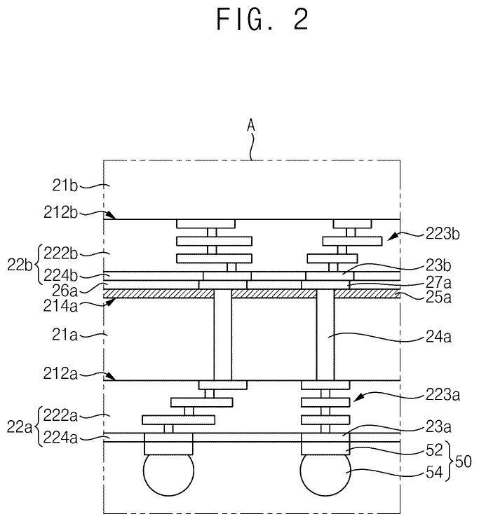

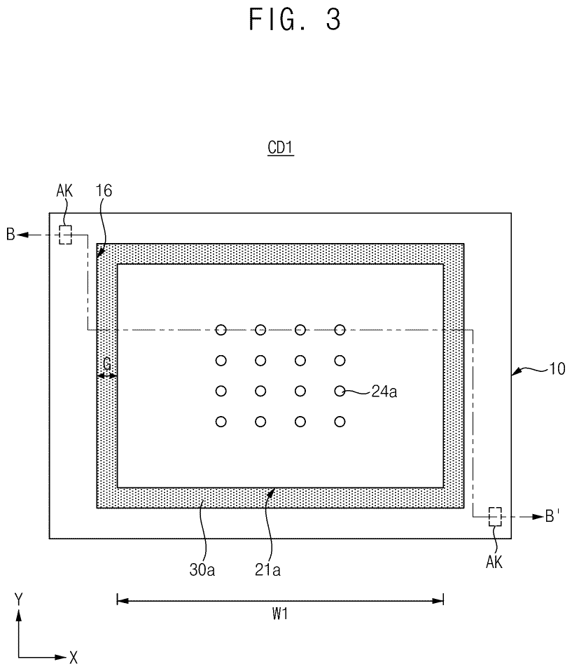

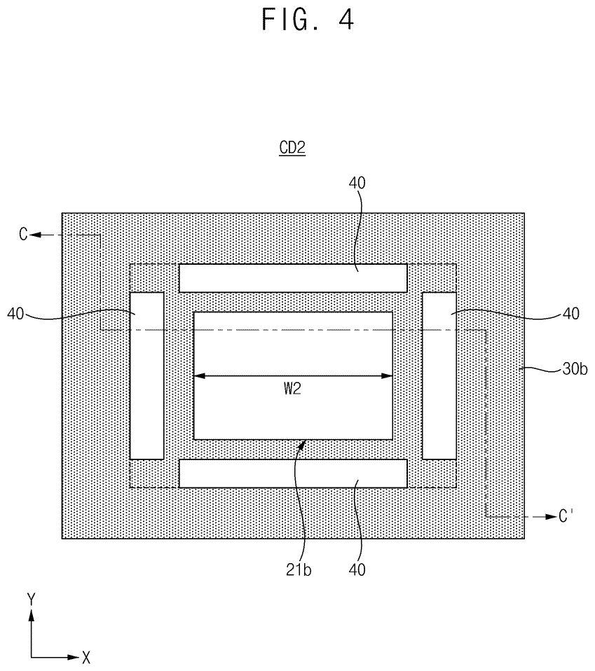

FIG. 1 is a cross-sectional view illustrating a semiconductor device in accordance with example embodiments. FIG. 2 is an enlarged cross-sectional view illustrating portion ‘A’ in FIG. 1. FIG. 3 is a plan view illustrating a lower die structure in FIG. 1. FIG. 4 is a plan view illustrating an upper die structure in FIG. 1. FIG. 1 includes a cross section cut along the line B-B′ in FIG. 3 and a cross section cut along the line C-C′ in FIG. 4.

Referring to FIGS. 1 to 4, a semiconductor device, semiconductor packaging device, or semiconductor package 200 may include a first die structure CD1 having a first or lower semiconductor chip 20a and a second die structure CD2 stacked on the first die structure CD1 and having a second or upper semiconductor chip 20b that is bonded to the first semiconductor chip 20a. Additionally, the semiconductor device 200 may further include conductive bumps 50 provided on an outer surface of the first semiconductor chip 20a.

In example embodiments, the semiconductor device 200 may be a multi-chip package (MCP) including different types of semiconductor chips. The semiconductor device 200 may be a stack semiconductor chip as a chiplet package that includes a plurality of chiplet dies. The stack semiconductor chip may include the first semiconductor chip 20a as a first chiplet die in and the second semiconductor chip 20b as a second chiplet die. The first semiconductor chip 20a and the second semiconductor chips 20b may be small structural units or IP block units that constitutes a processor chip. The first semiconductor chip 20a and the second semiconductor chip 20b may be stacked on each other to provide a semiconductor chip with an independent function.

The semiconductor device 200 may be provided as a logic chip including a logic circuit. The logic chip may be a controller that controls memory elements of a memory chip. For example, the logic chip may be an ASIC serving as a host such as a CPU, GPU, or SOC, or a processor chip such as an application processor (AP). The memory chip may include DRAM, SRAM, etc.

In the illustrated embodiment, the semiconductor device 200 as a multi-chip package is illustrated as including two stacked first and second chiplet dies 20a and 20b. However, it is not limited thereto, and for example, the semiconductor device may include 4, 8, 12, or 16 stacked semiconductor chips.

In example embodiments, the first die structure CD1 as a lower die structure may include a support substrate 10 having a cavity 16 therein, a first semiconductor chip 20a disposed in the cavity 16, and a first gap filling layer 30a that fills a gap or space between an inner wall of the cavity 16 and the first semiconductor chip 20a. The second die structure CD2 as an upper die structure may be stacked on the first die structure CD1. The second die structure CD2 may include a second semiconductor chip 20b electrically connected to the first semiconductor chip 20a and a second gap filling layer 30b surrounding a side surface of the second semiconductor chip 20b.

As illustrated in FIG. 1, the support substrate 10 may have a first surface (upper surface) 12 and a second surface (lower surface) 14 opposite to the first surface 12. The support substrate 10 may have the cavity 16 in a middle or central region thereof. The support substrate 10 may include a body that surrounds the cavity 16. The cavity 16 may extend from the first surface 12 to the second surface 14 of the support substrate 10 or the body thereof. The support substrate 10 may include, for example, a glass substrate, a silicon substrate, a non-metallic or metallic plate, etc. A thickness of the support substrate 10 may be within a range of 10 μm to 50 μm.

The first semiconductor chip 20a may include a first substrate 21a and a first front insulating layer 22a, a plurality of first bonding pads 23a, a plurality of through electrodes 24a, a first backside insulating layer 26a and a plurality of second bonding pads 27a.

The first substrate 21a may have a first surface 212a and a second surface 214a opposite the first surface 212a. Circuit patterns may be formed on the first surface 212a of the first substrate 21a. The first surface 212a may be an active surface, and the second surface 214a may be an inactive surface. For example, the first substrate 21a may be a single crystal silicon substrate. The circuit patterns may include transistors, capacitors, diodes, etc. The circuit patterns may constitute circuit elements. Accordingly, the first semiconductor chip 20a may be a semiconductor device in which a plurality of circuit elements are formed.

As illustrated in FIG. 2, the first front insulating layer 22a may be provided on the first surface 212a of the first substrate 21a, that is, the active surface. The first front insulating layer 22a may include a plurality of insulating layers 222a, 224a and wirings 223a in the insulating layers. In addition, the first bonding pads 23a may be provided in an outermost or lowermost insulating layer of the first front insulating layer 22a.

For example, the first front insulating layer 22a may include a first metal wiring layer 222a and a first passivation layer 224a. The first metal wiring layer 222a may include a plurality of wirings 223a therein. For example, the first metal wiring layer 222a may include a metal wiring structure having the plurality of wirings 223a vertically stacked in buffer layers and insulating layers. The first bonding pad 23a may be formed on a lowermost wiring among the plurality of wirings 223a. For example, the wirings may include aluminum (Al), copper (Cu), tin (Sn), nickel (Ni), gold (Au), platinum (Pt), or an alloy thereof.

The first passivation layer 224a may be formed on the first metal wiring layer 222a and may expose at least a portion of the first bonding pad 23a. For example, an upper surface of the first bonding pad 23a may be coplanar with an upper surface of the first passivation layer 224a and/or a lower surface of the first bonding pad 23a may be coplanar with a lower surface of the first passivation layer 224a. The first passivation layer 224a may include a plurality of stacked insulating layers. For example, the first passivation layer 224a may include an oxide layer, silicon nitride or silicon carbonitride. The first passivation layer 224a may have a single-layer or multi-layer structure.

The first bonding pad 23a may be provided in the first passivation layer 224a. The first bonding pad 23a may be exposed through an outer surface of the first passivation layer 224a. Although not illustrated in the figures, an insulation interlayer may be provided on the first surface 212a of the first substrate 21a to cover the circuit patterns.

The through electrode 24a such as through silicon via (TSV) may vertically penetrate the insulation interlayer and may extend from the first surface 212a of the first substrate 21a to a predetermined depth or height. The through electrode 24a may contact an uppermost wiring of the metal wiring structure. Accordingly, the through electrode 24a may be electrically connected to the first bonding pad 23a through the wirings 223a.

The first backside insulating layer 26a may be formed on the second surface 214a of the first substrate 21a, that is, the backside surface. The second bonding pad 27a may be provided in the first backside insulating layer 26a. For example, the second bonding pad 27a may be disposed on an exposed surface of the through electrode 24a. An upper surface of the second bonding pad 27a may be coplanar with an upper surface of the first backside insulating layer 26a and/or a lower surface of the second bonding pad 27a may be coplanar with a lower surface of the first backside insulating layer 26a. The first backside insulating layer 26a may include silicon oxide, carbon-doped silicon oxide, silicon carbonitride (SiCN), etc. Accordingly, the first bonding pads 23a and the second bonding pad 27a may be electrically connected to each other by the through electrode 24a.

As illustrated in FIG. 3, the first gap filling layer 30a may fill a gap between an outer side surface of the first semiconductor chip 20a and an inner surface of the cavity 16 of the support substrate 10. The first gap filling layer 30a may cover or be on the first surface 12 of the support substrate 10. For example, the first gap filling layer 30a may include silicon oxide such as TEOS. The first gap filling layer may include an inorganic dielectric layer or an organic dielectric layer. The inorganic dielectric layer may include silicon oxide, silicon oxynitride, phosphosilicate glass (PSG), boro-phosphosilicate glass (BPSG), etc. The organic dielectric layer may include a polymer or the like. The first gap filling layer may include an insulating material having a coefficient of thermal expansion smaller than the support substrate 10. The first gap filling layer may have a hardness lower than the support substrate 10.

The support substrate 10 may have a first coefficient of thermal expansion, and the first gap filling layer 30a may have a second coefficient of thermal expansion that is greater than the first coefficient of thermal expansion.

The first front insulating layer 22a of the first semiconductor chip 20a may be exposed by the first gap filling layer 30a. An outer surface, that is, a lower surface of the first front insulating layer 22a may be coplanar with or located on the same plane as a lower surface of the first gap filling layer 30a. The lower surface of the first gap filling layer 30a and the second surface 14 of the support substrate 10 may be coplanar or located on the same plane.

The second surface 214a of the first substrate 21a of the first semiconductor chip 20a may be positioned a higher vertical level than the first surface 12 of the support substrate 10. The first backside insulating layer 26a of the first semiconductor chip 20a may extend laterally from the second surface 214a of the first substrate 21a to cover the first gap filling layer 30a.

In example embodiments, the second semiconductor chip 20b may be stacked on the first semiconductor chip 20a. The second semiconductor chip 20b may include a second substrate 21b, a second front insulating layer 22b, and a plurality of third bonding pads 23b.

Circuit patterns may be formed on a first surface 212b of the second substrate 21b, that is, an active surface. For example, the second substrate 21b may be a single crystal silicon substrate. The circuit patterns may include transistors, capacitors, diodes, etc. The circuit patterns may constitute circuit elements. Accordingly, the second semiconductor chip 20b may be a semiconductor device in which a plurality of circuit elements are formed.

The second front insulating layer 22b may be provided on the first surface 212b of the second substrate 21b, that is, the active surface. The second front insulating layer 22b may include a plurality of insulating layers 222b, 224b and wirings 223b in the insulating layers. In addition, the third bonding pads 23b may be provided in an outermost or lowermost insulating layer of the second front insulating layer 22b.

For example, the second front insulating layer 22b may include a second metal wiring layer 222b and a third passivation layer 224b. The second metal wiring layer 222b may include a plurality of wirings 223b therein. For example, the second metal wiring layer 222b may include a metal wiring structure including a plurality of wirings 223b vertically stacked in buffer layers and insulating layers. The third bonding pad 23b may be formed on a lowermost wiring among the plurality of wirings 223b. For example, the wirings may include aluminum (Al), copper (Cu), tin (Sn), nickel (Ni), gold (Au), platinum (Pt), or an alloy thereof.

The third passivation layer 224b may be formed on the second metal wiring layer 222b and may expose at least a portion of the third bonding pad 23b. For example, an upper surface of the third bonding pad 23b may be coplanar with an upper surface of the third passivation layer 224b and/or a lower surface of the third bonding pad 23b may be coplanar with a lower surface of the third passivation layer 224b. The third passivation layer 224b may include a plurality of stacked insulating layers. For example, the third passivation layer 224b may include silicon oxide, silicon nitride, or silicon carbonitride. The third passivation layer 224b may have a single-layer or multi-layer structure.

The third bonding pad 23b may be provided in the third passivation layer 224b. The third bonding pad 23b may be exposed through an outer surface of the third passivation layer 224b.

As illustrated in FIG. 2, the first semiconductor chip 20a and the second semiconductor chip 20b may be bonded to each other by hybrid bonding. The front surface 212b of the second substrate 21b of the second semiconductor chip 20b may face or face away from the backside surface 214a of the first substrate 21a of the first semiconductor chip 20a. The second front insulating layer 22b of the second semiconductor chip 20b and the first backside insulating layer 26a of the first semiconductor chip 20a may be directly bonded to each other. Accordingly, the second bonding pad 27a of the first semiconductor chip 20a and the third bonding pad 23b of the second semiconductor chip 20b may be bonded to each other by Cu-Cu hybrid bonding (pad to pad direct bonding).

The first backside insulating layer 26a of the first semiconductor chip 20a and the second front insulating layer 22b of the second semiconductor chip 20b may be directly bonded to each other. The first backside insulating layer 26a and the second front insulating layer 22b may make contact with each other to provide a bonding structure by including an insulating material providing excellent bonding strength. The first backside insulating layer 26a and the second front insulating layer 22b may be bonded to each other by a high-temperature annealing process while in contact with each other. At this time, the bonding structure may have a relatively stronger bonding strength by covalent bonding.

In example embodiments, the second gap filling layer 30b may cover or be on an outer side surface of the second semiconductor chip 20b. An outer side surface of the second front insulating layer 22b of the second semiconductor chip 20b may be exposed from the second gap filling layer 30b. A lower surface of the second front insulating layer 22b of the second semiconductor chip 20b may be coplanar with or located on the same plane as a lower surface of the second gap filling layer 30b. An upper surface of the second semiconductor chip 20b may be coplanar with or located on the same plane as an upper surface of the second gap filling layer 30b. For example, the second gap filling layer 30b may include the same material as the first gap filling layer 30a. The second gap filling layer 30b may include silicon oxide such as TEOS.

In example embodiments, the second die structure CD2 may further include at least one dummy chip 40. The first semiconductor chip 20a may have a first size, and the second semiconductor chip 20b may have a second size smaller than the first size. The first semiconductor chip 20a may have a first width W1, and the second semiconductor chip 20b may have a second width W2 that is smaller than the first width. The second semiconductor chip 20b may be disposed on or vertically overlap a middle region of the first semiconductor chip 20a, and a plurality of dummy chips 40 may be disposed on a peripheral region of the first semiconductor chip 20a around (e.g., surrounding) the upper semiconductor chip 20b. The dummy chips 40 may be silicon dummy chips that are formed to a desired size by cutting a silicon wafer.

As illustrated in FIG. 4, for example, four dummy chips 40 may be disposed along four sides of the second semiconductor chip 20b when viewed in plan view. The second gap filling layer 30b may fill gaps or spaces between the second semiconductor chip 20b and the dummy chips 40. The second gap filling layer 30b may cover or surround outer side surfaces of the dummy chips 40. Lower surfaces of the dummy chips 40 may be exposed from the second gap filling layer 30b. The lower surfaces of the dummy chips 40 may be coplanar with or located on the same plane as the lower surface of the second gap filling layer 30b. Upper surfaces of the dummy chips 40 may be exposed from the second gap filling layer 30b. The upper surfaces of the dummy chips 40 may be coplanar with or located on the same plane as an upper surface of the second gap filling layer 30b.

The outer side surface of the second gap filling layer 30b may be coplanar with or located on the same plane as an outer side surface of the substrate 10, which may be or include glass. The outer side surface of the second gap filling layer 30b may be coplanar with or located on the same plane as the outer side surface of the first gap filling layer 30a.

In example embodiments, the dummy chips 40 may be arranged around the second semiconductor chip 20b so that a silicon ratio in the second die structure CD2 and a silicon ratio in the first die structure CD1 are adjusted to be similar to each other. Since the silicon ratio in the first die structure CD1 and the silicon ratio in the second die structure CD2 are similar to each other, warpage of the stacked first and second die structures CD1 and CD2 may be prevented.

In example embodiments, the support substrate 10 may have a first coefficient of thermal expansion, and the first gap filling layer 30a may have a second coefficient of thermal expansion that is greater than the first coefficient of thermal expansion. Since the support substrate 10 including glass has a more dense composition than the first gap filling layer 30a, the support substrate 10 may have excellent mechanical strength and thermal resistance characteristics according to temperature changes compared to the first gap filling layer 30a. When viewed in plan view, an area ratio occupied by the support substrate 10 to the total area of the first die structure CD may be within a range of 10% to 50%. The ratio occupied by the support substrate 10 in the first die structure CD1 may be greater or less than a ratio occupied by the first gap filling layer 30a. By adjusting the ratio occupied by the support substrate 10, warpage of the first die structure CD1 may be reduced or controlled.

In example embodiments, the conductive bumps 50 may be disposed on the first bonding pads 23a on the first front insulating layer 22a of the first semiconductor chip 20a, respectively. For example, each of the conductive bumps 50 may include a pillar bump 52 on the first bonding pad 23a and a solder bump 54 on the pillar bump 52. For example, the pillar bump may include copper (Cu), aluminum (Al), tin (Sn), nickel (Ni), gold (Au), platinum (Pt), or an alloy thereof. The solder bump may include solder. The semiconductor package 200 may be mounted on a substrate such as a package substrate, an interposer, or a redistribution wiring layer via the conductive bumps 50 to form a further semiconductor package.

As mentioned above, the semiconductor package 200 may include the first die structure CD1 and the second die structure CD2 stacked on the first die structure CD1. The first die structure CD1 may include the support substrate 10 having the cavity 16 therein, the first semiconductor chip 20a disposed in the cavity 16, and the first gap filling layer 30a that fills the gap between the inner wall of the cavity 16 and the first semiconductor chip 20a. The second die structure CD2 may include the second semiconductor chip 20b electrically connected to the first semiconductor chip 20a and the second gap filling layer 30b surrounding the second semiconductor chip 20b.

The support substrate 10 may have the first coefficient of thermal expansion, and the first gap filling layer 30a may have the second coefficient of thermal expansion that is greater than the first coefficient of thermal expansion. Since the support substrate 10 containing glass has a more dense composition than the first gap filling layer 30a, the support substrate 10 may have excellent mechanical strength and thermal resistance characteristics according to temperature changes compared to the first gap filling layer 30a. Accordingly, the ratio occupied by the support substrate 10 may be adjusted to reduce or control warpage of the first die structure CD1.

Hereinafter, a method of manufacturing the semiconductor package of FIG. 1 will be described.

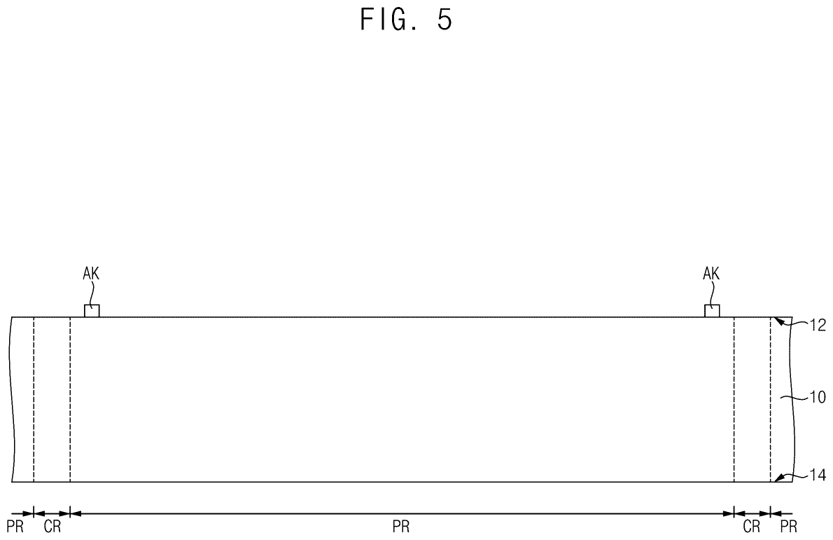

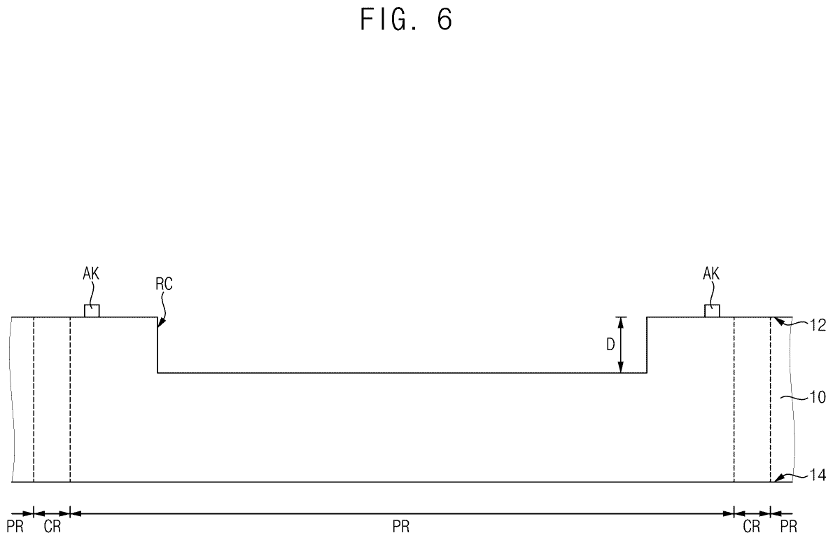

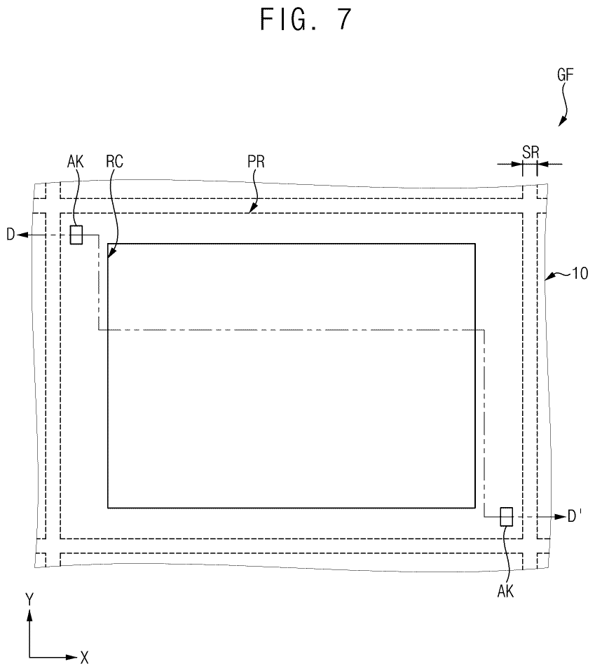

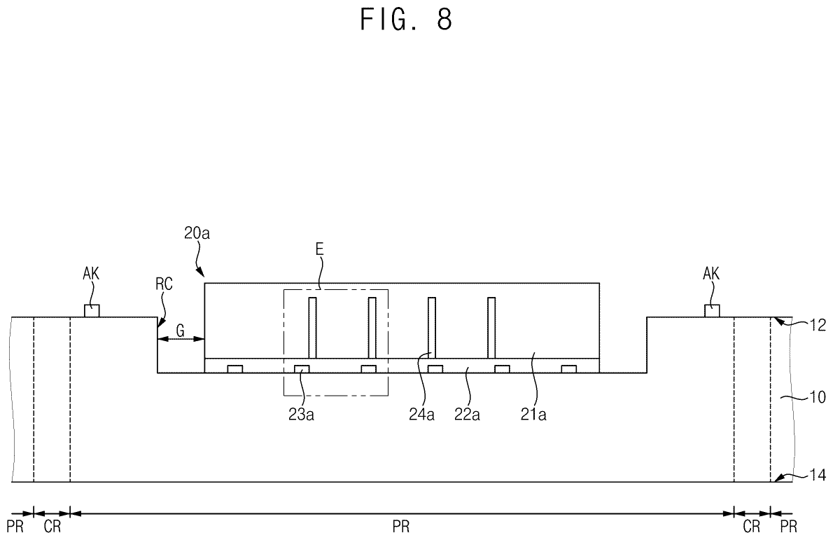

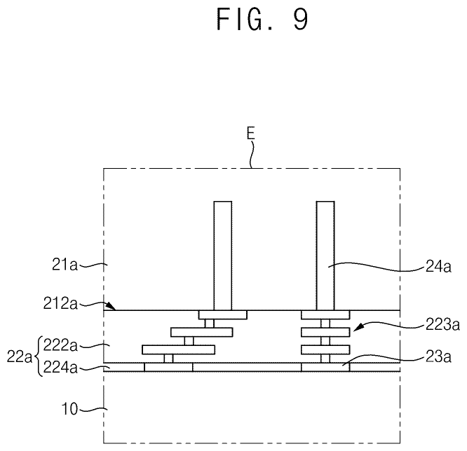

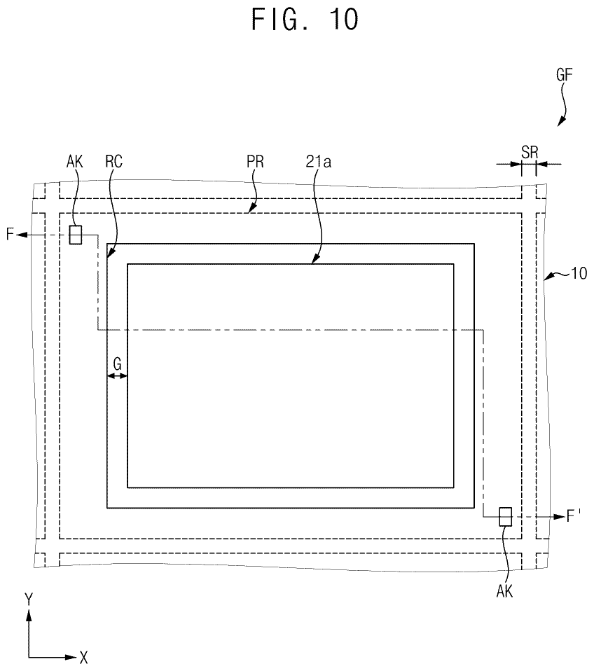

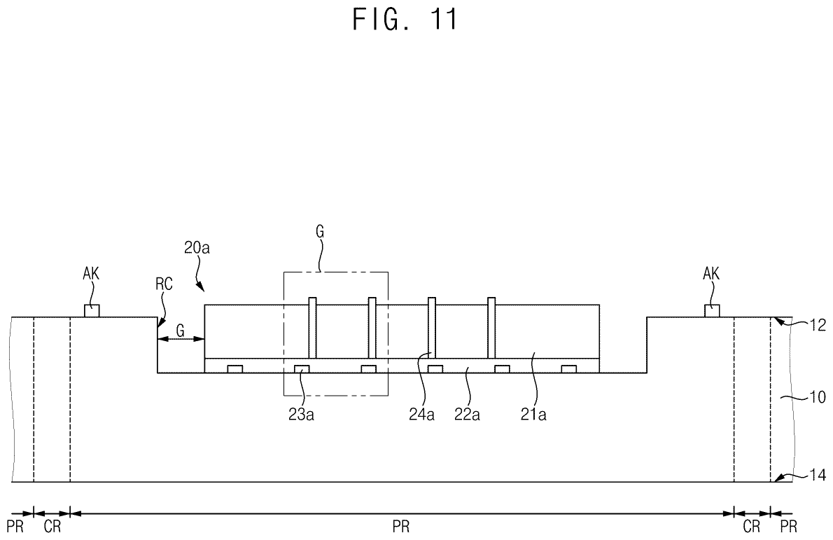

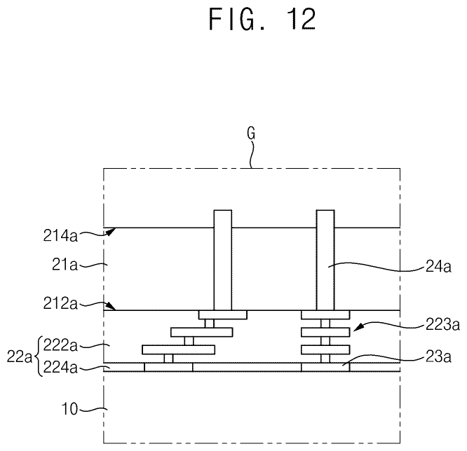

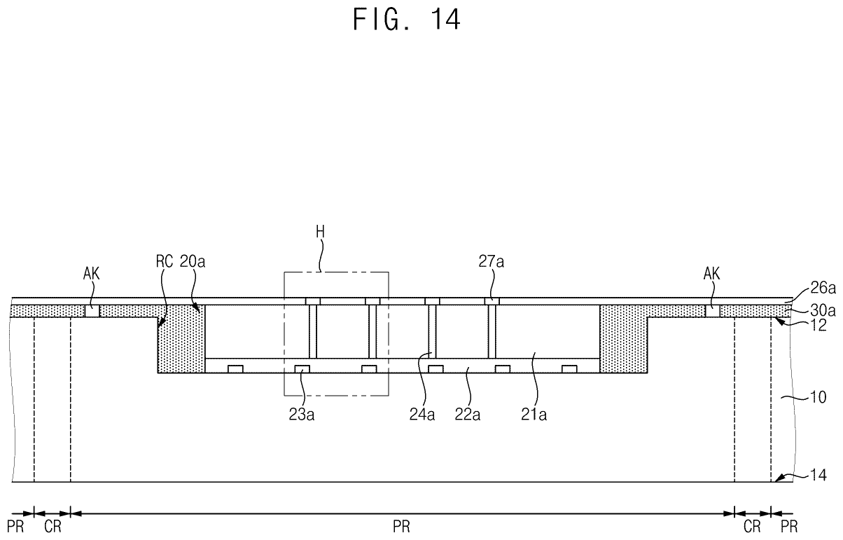

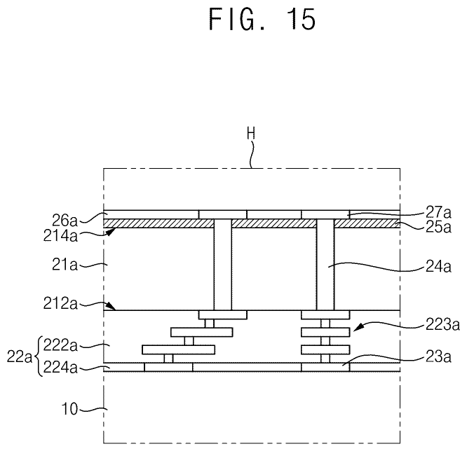

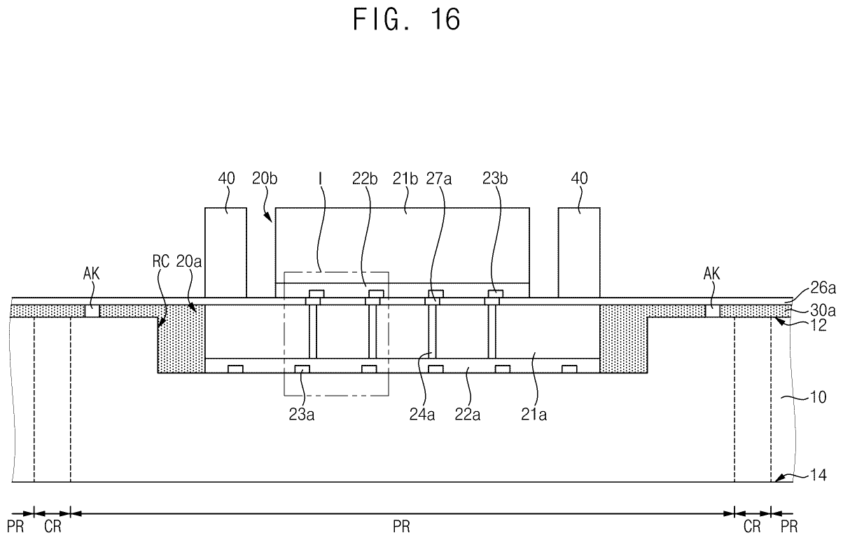

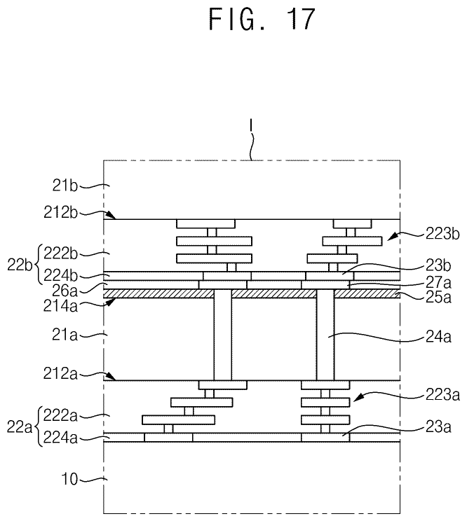

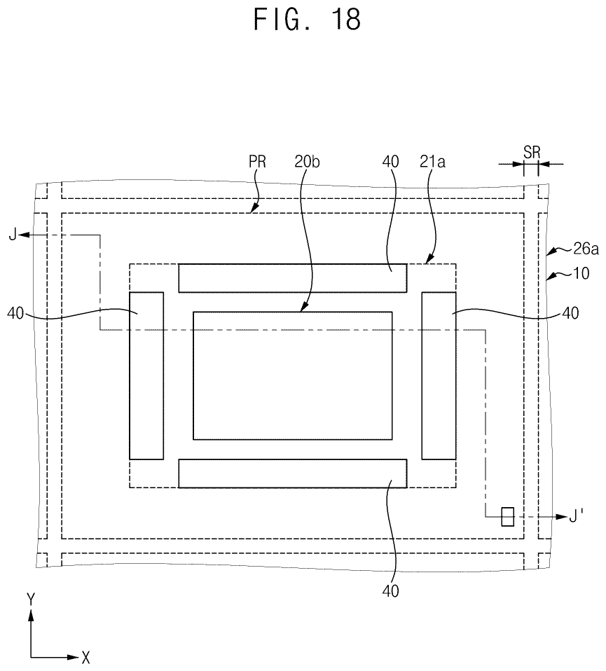

FIGS. 5 to 25 are views illustrating a method of manufacturing a semiconductor package in accordance with example embodiments. FIGS. 5, 6, 8, 9, 11 to 17 and 19 to 25 are cross-sectional views illustrating a method of manufacturing a semiconductor packaging device in accordance with example embodiments. FIG. 9 is an enlarged cross-sectional view illustrating portion ‘E’ in FIG. 8. FIG. 12 is an enlarged cross-sectional view illustrating portion ‘G’ in FIG. 11. FIG. 15 is an enlarged cross-sectional view illustrating portion ‘H’ in FIG. 14. FIG. 17 is an enlarged cross-sectional view illustrating portion ‘I’ in FIG. 16. FIG. 7 is a plan view of FIG. 6. FIG. 6 is a cross-sectional view taken along the line D-D′ in FIG. 7. FIG. 10 is a plan view of FIG. 8. FIG. 8 is a cross-sectional view taken along the line F-F′ in FIG. 10. FIG. 18 is a plan view of FIG. 16. FIG. 16 is a cross-sectional view taken along the line J-J′ in FIG. 18.

Referring to FIGS. 5 to 7, a support frame GF including a recess RC formed therein may be prepared.

In example embodiments, the support frame GF may be provided as a carrier substrate on which a first or lower semiconductor chip (lower die) is placed in the recess RC and a second or upper semiconductor chip (upper die) is stacked on the lower semiconductor chip. The support frame GF may have a shape corresponding to a wafer or a panel on which a semiconductor process is performed. For example, the support frame GF may include a glass substrate, a silicon substrate, a non-metallic or metallic plate, etc.

The support frame GF may include a glass substrate 10 that has a first surface 12 and a second surface 14 opposite to the first surface 12. The support frame GF may include a package region PR on which the lower semiconductor chip is mounted and a cutting region CR surrounding the package region PR. As will be described below, the support frame GF may be cut along the cutting region CR to form an individual support substrate that surrounds the lower semiconductor chip. The support substrate may be used as a core substrate to reduce or control warpage of the lower semiconductor chip.

As illustrated in FIG. 5, first, alignment key patterns AK may be formed on the first surface 12 of the support frame GF. For example, an oxide layer may be formed on the first surface 12 of the glass substrate 10, and a patterning process and a plating process may be performed on the oxide layer to form the alignment key patterns AK. The alignment key patterns AK may include a metal material such as aluminum or copper. The alignment key patterns AK may be formed in a peripheral region within the package region PR or within the cutting region CR. A process of attaching the lower semiconductor chip (and/or upper semiconductor chip) may be performed using the alignment key patterns AK.

As illustrated in FIGS. 6 and 7, the recess RC may be formed in the first surface 12 of the support frame GF to accommodate the lower semiconductor chip. The recesses RC may be formed respectively in the package regions PR of the support frame GF. The recess RC may be formed by a plasma etching process. Alternatively, the recess RC may be formed by a laser drilling process, a wet etching process, etc.

The recess RC may be formed to correspond to a region in which the lower semiconductor chip is disposed. The recess RC may have an area greater than an area of the lower semiconductor chip. The recess RC may have a predetermined depth D from the first surface 12 of the glass substrate 10. The predetermined depth D of the recess RC may be within a range of 10 μm to 50 μm. The area and depth of the recess RC may be determined in consideration of an occupation ratio of the glass substrate 10 required to control warpage of the lower semiconductor chip.

Referring to FIGS. 8 to 10, a lower semiconductor chip 20a may be disposed in the recess RC of the glass substrate 10.

In example embodiments, the lower semiconductor chip 20a individualized through a sawing process from a wafer may be placed in the recess RC of the glass substrate 10. A front surface of the lower semiconductor chip 20a may be stacked to face the glass substrate 10. An upper portion of the lower semiconductor chip 20a may be exposed from the recess RC. The lower semiconductor chip 20a may be a first chiplet die (lower chiplet die). The lower semiconductor chip 20a may be a small structural unit or IP block unit of a processor chip. The first chiplet die may form one chip together with the upper semiconductor chip as a second chiplet die.

As illustrated in FIGS. 8 and 9, the lower semiconductor chip 20a may include a first substrate 21a and a first front insulating layer 22a having first bonding pads 23a on an outer or lower surface thereof. Additionally, the lower semiconductor chip 20a may further include a plurality of through electrodes 24a that are provided in the first substrate 21a and are electrically connected to the first bonding pads 23a.

The first substrate 21a may have a first surface 212a and a second surface 214a opposite the first surface 212a. Circuit patterns may be formed on the first surface 212a of the first substrate 21a. For example, the first substrate 21a may include silicon, germanium, silicon-germanium, or III-V compounds, e.g., GaP, GaAs, GaSb, etc. In some embodiments, the first substrate 21a may be a silicon-on-insulator (SOI) substrate, or a germanium-on-insulator (GOI) substrate.

The circuit patterns may include transistors, capacitors, diodes, etc. The circuit patterns may constitute circuit elements. Accordingly, the first semiconductor chip may be a semiconductor device in which a plurality of circuit elements are formed. The circuit patterns may be formed by performing a Fab process called a Front End of Line (FEOL) process for manufacturing semiconductor devices on the first surface 212a of the first substrate 21a. A surface of the first substrate on which the FEOL process is performed may be referred to as a front surface of the first substrate, and a surface opposite to the front surface may be referred to as a backside surface.

The circuit element may include a plurality of memory devices. Examples of the memory device include a volatile semiconductor memory device and a non-volatile semiconductor memory device. Examples of the volatile semiconductor memory device include DRAM, SRAM, etc. Examples of the non-volatile semiconductor memory device include EPROM, EEPROM, Flash EEPROM, etc.

The first front insulating layer 22a as an insulation interlayer may be formed on the first surface 212a of the first substrate 21a, that is, the front surface. The first front insulating layer 22a may include a plurality of insulating layers 222a and 224a and wirings 223a in the insulating layers. In addition, the first bonding pads 23a may be provided in an outermost or lowermost insulating layer of the first front insulating layer 22a.

For example, the first front insulating layer 22a may include a first metal wiring layer 222a and a first passivation layer 224a. The first metal wiring layer 222a may include a plurality of wirings 223a therein. For example, the first metal wiring layer 222a may include a metal wiring structure having the plurality of wirings 223a vertically stacked in buffer layers and insulating layers. The first bonding pad 23a may be formed on an lowermost wiring among the plurality of wirings 223. For example, the wirings may include aluminum (Al), copper (Cu), tin (Sn), nickel (Ni), gold (Au), platinum (Pt), or an alloy thereof.

The first passivation layer 224a may be formed on the first metal wiring layer 222a and may expose at least a portion of the first bonding pad 23a. The first passivation layer 224a may include a plurality of stacked insulating layers. For example, the first passivation layer 224a may include an oxide layer, silicon nitride or silicon carbonitride. The first passivation layer 224a may have a single-layer or multi-layer structure.

The first bonding pad 23a may be provided in the first passivation layer 224a. The first bonding pad 23a may be exposed through an outer surface (or upper and/or lower surfaces) of the first passivation layer 224a. Although not illustrated in the figures, an insulation interlayer may be provided on the first surface 212a of the first substrate 21a to cover the circuit patterns. The insulation interlayer may be formed of, for example, silicon oxide or a low dielectric material. The insulation interlayer may include lower wirings therein that are electrically connected to the circuit patterns. Accordingly, the circuit pattern may be electrically connected to the first bonding pad 23a by the lower wirings and the wirings.

A through electrode 24a such as through silicon via (TSV) may vertically penetrate the insulation interlayer and may extend from the first surface 212a of the first substrate 21a to a predetermined depth. The through electrode 24a may contact an uppermost wiring of the metal wiring structure. Accordingly, the through electrode 24a may be electrically connected to the first bonding pad 23a through the wirings 223a.

A liner layer may be provided on an outer surface of the through electrode 24a. The liner layer may include silicon oxide or carbon-doped silicon oxide. The liner layer may electrically insulate the through electrode 24a from the first substrate 21a and the first metal wiring layer 222a.

The through electrode 24a and the first bonding pad 23a may include the same metal. For example, the metal may include copper (Cu). However, it may not be limited thereto, and may include a material (e.g., gold (Au)) that can be combined by interdiffusion of metals by a high-temperature annealing process.

As illustrated in FIG. 10, an outer side surface of the lower semiconductor chip 20a may be spaced apart from an inner surface of the recess RC. A gap G between the outer side surface of the lower semiconductor chip 20a and the inner surface of the recess RC may be within a range of 5 μm to 10 μm.

Referring to FIGS. 11 and 12, the second surface 214a of the first substrate 21a may be partially removed to expose an end portion of the through electrode 24a.

In example embodiments, first, a grinding process such as a back lap process may be performed to partially remove the second surface 214a of the first substrate 21a, and then an etching process such as a silicon recess process may be performed to expose the end portion of the through electrode 24a. Accordingly, a thickness of the first substrate 21a may be reduced to a desired thickness. For example, the thickness of the first substrate 21a may be in a range of from about 20 μm to about 100 μm.

In the back lap process, the entire backside surface of the first substrate 21a may be ground. The silicon recess process may selectively etch only silicon in the backside surface of the first substrate 21a. The etching process may be an isotropic dry etching process. The etching process may include a plasma etching process. The plasma etching process may be performed using inductively coupled plasma, capacitively coupled plasma, microwave plasma, etc.

Accordingly, the end portions of the through electrodes 24a may have the same heights from the second surface 214a of the first substrate 21a.

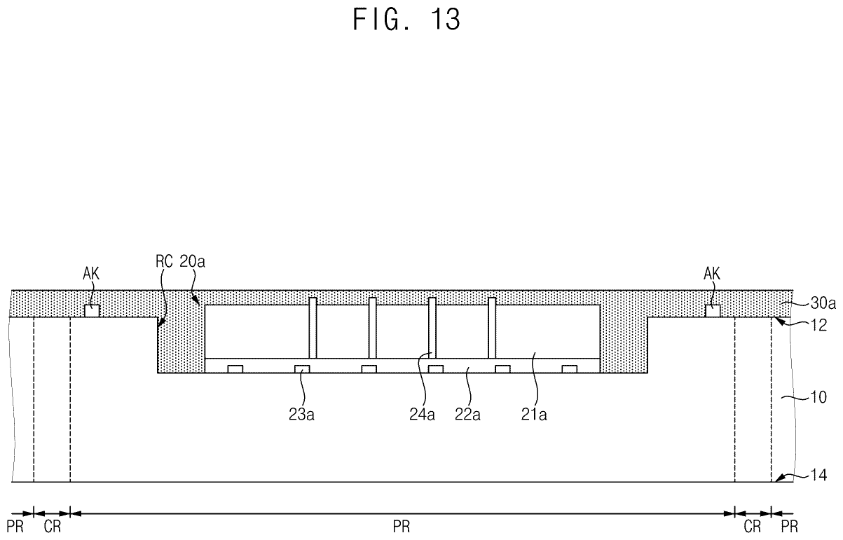

Referring to FIG. 13, a first gap filling layer 30a may be formed on the first surface 12 of the support frame GF to cover the lower semiconductor chip 20a.

In example embodiments, the first gap filling layer 30a may be formed to fill the gap between the outer side surface of the lower semiconductor chip 20a and the inner surface of the recess RC. The first gap filling layer 30a may be formed to cover the first surface 12 of the glass substrate 10. The first gap filling layer 30a may be formed to fill the gap between the protruding end portions of the through electrodes 24a on the second surface 214a of the first substrate 21a. The first gap filling layer 30a may include silicon oxide such as TEOS.

Referring to FIGS. 14 and 15, a first backside insulating layer 26a having second bonding pads 27a therein (e.g., in an outer surface thereof) may be formed on the second surface 214a of the first substrate 21a.

First, an upper portion of the first gap filling layer 30a may be removed to expose an end portion of the through electrodes 24a. At this time, the second surface 214a of the first substrate 21a may be exposed.

Then, a polishing stop layer may be formed on the second surface 214a of the first substrate 21a, and a sacrificial layer may be formed on the polishing stop layer. The polishing stop layer may be formed conformally to cover the end portions of the through electrodes 24a that protrude from the second surface 214a of the first substrate 21a. The polishing stop layer may cover the entire second surface 214a of the first substrate 21a. The polishing stop layer may include a material that can be used to detect a polishing end point in a following chemical mechanical polishing process. The polishing stop layer may include a silicon nitride layer. The thickness and material of the polishing stop layer may be selected in consideration of a polishing selectivity ratio and polishing conditions in the following chemical mechanical polishing process.

The sacrificial layer may be formed on the polishing stop layer to fill a gap between the protruding end portions of the through electrodes 24a. The sacrificial layer may include silicon oxide such as TEOS.

Then, a chemical mechanical polishing (CMP) process using the polishing stop layer to detect a polishing end point may be performed to remove the sacrificial layer to expose the end portions of the through electrodes 24a. Through the CMP process, the end portions of the through electrodes 24a and portions of the polishing stop layer covering them may be removed to form a polishing stop layer pattern 25a on the second surface 214a of the first substrate 21a.

The polishing stop layer pattern 25a may expose the end portions of the through electrodes 24a. The end portions of the through electrodes 24a may protrude from the second surface 214a of the first substrate 21a, and the polishing stop layer pattern 25a may cover or surround side walls of the end portions of the through electrodes 24a that protrude from the second surface 214a of the first substrate 21a. Accordingly, upper surfaces of the through electrodes 24a may be exposed by the polishing stop layer pattern 25a. An upper surface of the polishing stop layer pattern 25a and the exposed upper surfaces of the through electrodes 24a may be coplanar or positioned on the same plane.

Then, the first backside insulating layer 26a as a second passivation layer having the second bonding pad 27a that is electrically connected to the through electrode 24a may be formed on the polishing stop layer pattern 25a on the second surface 214a of the first substrate 21a.

For example, after the first backside insulating layer 26a is formed on the polishing stop layer pattern 25a on the second surface 214a of the first substrate 21a, an opening may be formed in the first backside insulating layer 26a to expose the through electrode 24a and a plating process may be performed to form the second bonding pad 27a. The second bonding pad 27a may be disposed on the exposed upper surface of the through electrode 24a. The first backside insulating layer 26a may include silicon oxide, carbon-doped silicon oxide, silicon carbonitride (SiCN), etc. Accordingly, the first bonding pads 23a and the second bonding pads 27a may be electrically connected to each other by the through electrode 24a.

Alternatively, in order to simplify the processes, the step of forming the polishing stop layer pattern 25a may be omitted. In this case, after forming an oxide layer such as a sacrificial layer on the second surface 214a of the first substrate 21a to cover the protruding end portions of the through electrodes 24a, an upper portion of the oxide layer may be removed to expose the protruding end portions of the through electrodes 24a, and the first backside insulating layer 26a may be formed on the oxide layer.

Referring to FIGS. 16 to 18, an upper semiconductor chip 20b may be attached on the lower semiconductor chip 20a within the support frame GF (die-to-wafer hybrid bonding process).

In example embodiments, the upper semiconductor chip 20b may be disposed on the lower semiconductor chip 20a. Front surfaces of the lower and upper semiconductor chips 20a and 20b may face the support frame GF.

For example, a die bonding apparatus may pick up the upper semiconductor chip 20b individualized through a sawing process and may bond it to the lower semiconductor chip 20a. The die bonding apparatus may attach the upper semiconductor chip 20b to the lower semiconductor chip 20a by performing a thermal compression process at a predetermined temperature (for example, about 400° C. or less). By the thermal compression process, the upper semiconductor chip 20b and the lower semiconductor chip 20a may be bonded to each other through hybrid bonding. That is, the front surface of the upper semiconductor chip 20b, that is, a second front insulating layer 22b on a second surface 212b of a second substrate 21b may be directly bonded to a backside surface of the lower semiconductor chip 20a, that is, the backside insulating layer 26a on the second surface 214a of the first substrate 21a.

As illustrated in FIG. 17, the upper semiconductor chip 20b may include the second substrate 21b and the second front insulating layer 22b having third bonding pads 23b therein (e.g., in an outer surface thereof). The second substrate 21b may have a first surface 212b and a second surface 214b opposite the first surface 212b. Circuit patterns may be formed on the first surface 212b of the second substrate 21b.

The second front insulating layer 22b as an insulation interlayer may be formed on the first surface 212b of the second substrate 21b, that is, the front surface. The second front insulating layer 22b may include a plurality of insulating layers 222b and 224b and wirings 223b in the insulating layers. In addition, the third bonding pads 23b may be provided in an lowermost insulating layer of the second front insulating layer 22b.

For example, the second front insulating layer 22b may include a second metal wiring layer 222b and a third passivation layer 224b. The second metal wiring layer 222b may include a plurality of wirings 223b therein. For example, the second metal wiring layer 222b may include a metal wiring structure including a plurality of wirings 223b vertically stacked in buffer layers and insulating layers. The third bonding pad 23b may be formed on a lowermost wiring among the plurality of wirings 223b. For example, the wirings may include aluminum (Al), copper (Cu), tin (Sn), nickel (Ni), gold (Au), platinum (Pt), or an alloy thereof.

The third passivation layer 224b may be formed on the second metal wiring layer 222b and may expose at least a portion of the third bonding pad 23b. The third passivation layer 224b may include a plurality of stacked insulating layers. For example, the third passivation layer 224b may include silicon oxide, silicon nitride, or silicon carbonitride. The third passivation layer 224b may have a single-layer or multi-layer structure.

The third bonding pad 23b may be provided in the third passivation layer 224b. The third bonding pad 23b may be exposed through an outer surface of the third passivation layer 224b. An upper surface of the third bonding pad 23b may be coplanar with an upper surface of the third passivation layer 224b and/or a lower surface of the third bonding pad 23b may be coplanar with a lower surface of the third passivation layer 224b. Although not illustrated in the figures, an insulation interlayer may be provided on the first surface 212b of the second substrate 21b to cover the circuit patterns. The insulation interlayer may be formed to include, for example, silicon oxide or a low dielectric material. The insulation interlayer may include lower wirings that are electrically connected to the circuit patterns. Accordingly, the circuit pattern may be electrically connected to the third bonding pad 23b through the lower wirings and the wirings.

The upper semiconductor chip 20b may be a second chiplet die (upper chiplet die). The upper semiconductor chip 20b may be a small structural unit or IP block unit of the processor chip. The second chiplet die may form one chip together with the lower semiconductor chip as the first chiplet die.

The lower semiconductor chip 20a may have a first size, and the upper semiconductor chip 20b may have a second size smaller than the first size. The lower semiconductor chip 20a may have a first width, and the upper semiconductor chip 20b may have a second width that is smaller than the first width.

In example embodiments, a plurality of dummy chips 40 may be disposed on the lower semiconductor chip 20a. The upper semiconductor chip 20b may be arranged on a middle or central region of the lower semiconductor chip 20a, and the plurality of dummy chips 40 may be arranged on a peripheral region of the lower semiconductor chip 20a around (e.g., surrounding) the upper semiconductor chip 20b. The dummy chips 40 may be formed into a desired size by cutting a silicon wafer.

As illustrated in FIG. 18, for example, four dummy chips 40 may be disposed along four sides of the upper semiconductor chip 20a when viewed in plan view, but the present inventive concept is not limited thereto.

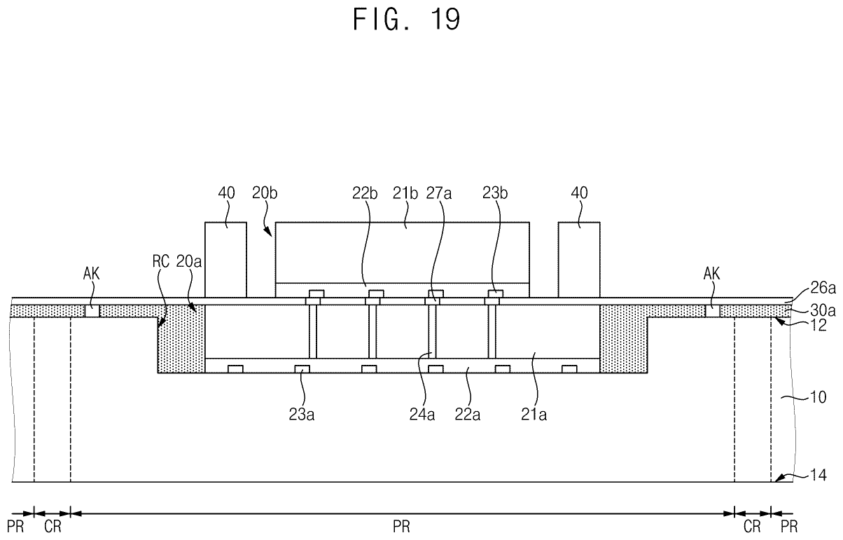

Referring to FIG. 19, upper portions of the upper semiconductor chip 20b and the dummy chips 40 may be removed to have desired heights. The upper portions of the upper semiconductor chip 20b and the dummy chips 40 may be removed through a grinding process. The dummy chips 40 may be disposed around the upper semiconductor chip 20b to provide a silicon material ratio similar to that of the lower semiconductor chip 20a.

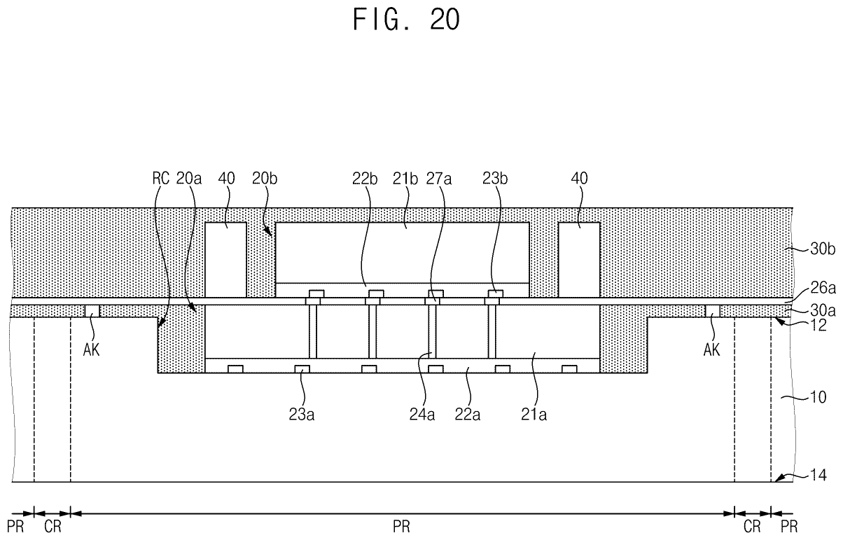

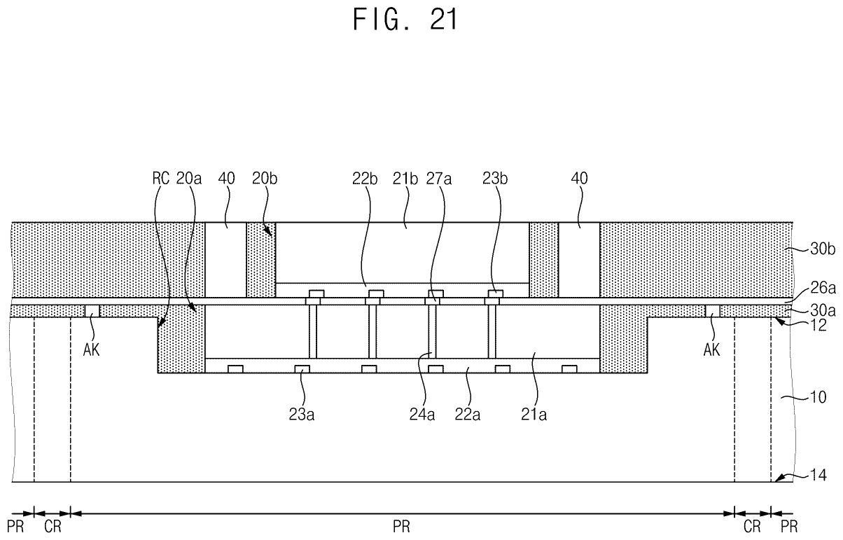

Referring to FIGS. 20 and 21, a second gap filling layer 30b may be formed on the first gap filling layer 30a to cover the upper semiconductor chip 20b and the dummy chips 40, and an upper portion of the second gap filling layer 30b may be removed to expose upper surfaces of the upper semiconductor chip 20b and the dummy chips 40. The upper surfaces of the upper semiconductor chip 20b and the dummy chips 40 may be coplanar.

In example embodiments, the second gap filling layer 30b may be formed to fill gaps between the upper semiconductor chip 20b and the dummy chips 40. For example, the second gap filling layer 30b may include the same material as the first gap filling layer 30a. The second gap filling layer may include silicon oxide such as TEOS.

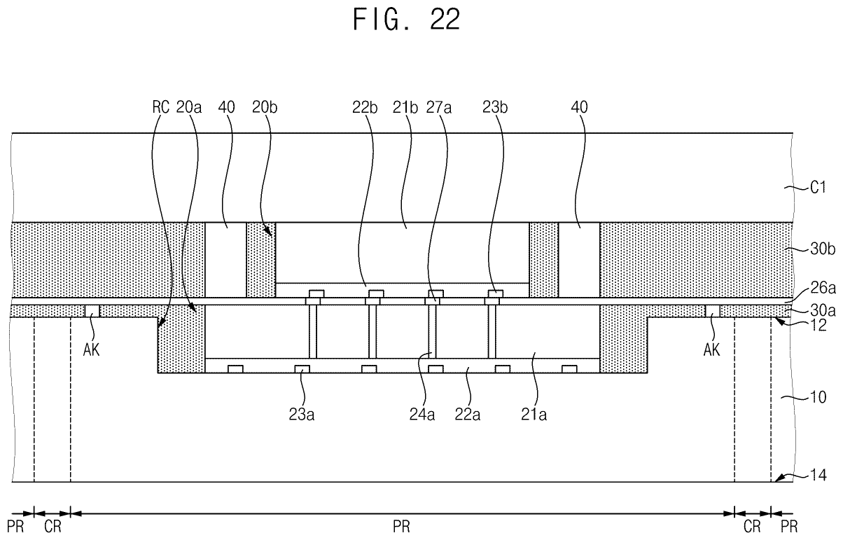

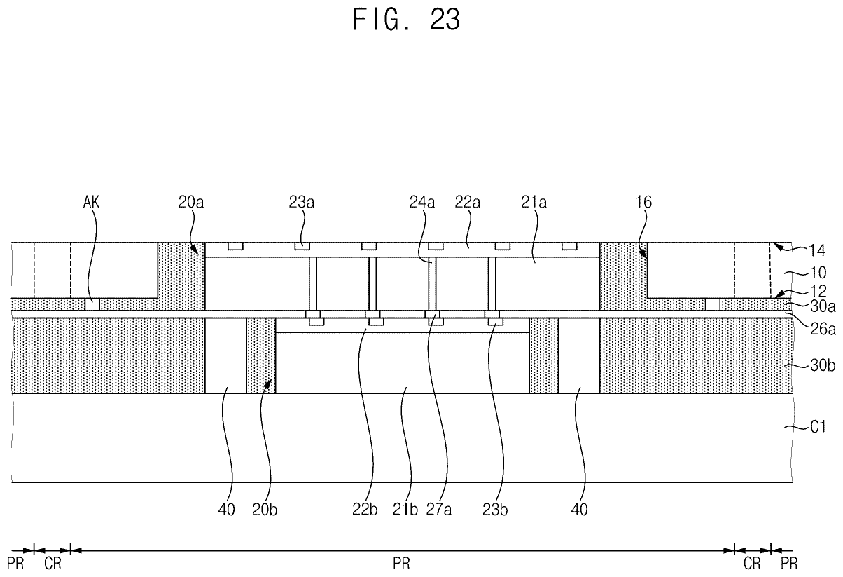

Referring to FIGS. 22 and 23, the second surface 14 of the glass substrate 10 may be partially removed to expose the lower semiconductor chip 20a.

As illustrated in FIG. 22, a carrier substrate C1 may be attached on the second gap filling layer 30b. The carrier substrate C1 may be attached to the upper surfaces of the upper semiconductor chip 20b and the dummy chips 40 exposed by the second gap filling layer 30b.

As illustrated in FIG. 23, the structure of FIG. 22 may be turned over, and the second surface 14 of the glass substrate 10 may be removed to expose the first front insulating layer 22a of the lower semiconductor chip 20a. At this time, a lower surface of the recess RC may be exposed to form a cavity 16. The cavity 16 may extend from the first surface 12 to the second surface 14 of the glass substrate 10. The first front insulating layer 22a of the lower semiconductor chip 20a may be exposed by the cavity 16. The first front insulating layer 22a of the lower semiconductor chip 20a may be horizontally offset from the cavity 16. Accordingly, the first bonding pads 23a within the first front insulating layer 22a may be exposed.

Accordingly, the lower semiconductor chip 20a may be disposed in the cavity 16 of the glass substrate 10, and the first gap filling layer 30a may fill the gap between the outer side surface of the lower semiconductor chip 20a and an inner surface of the cavity 16.

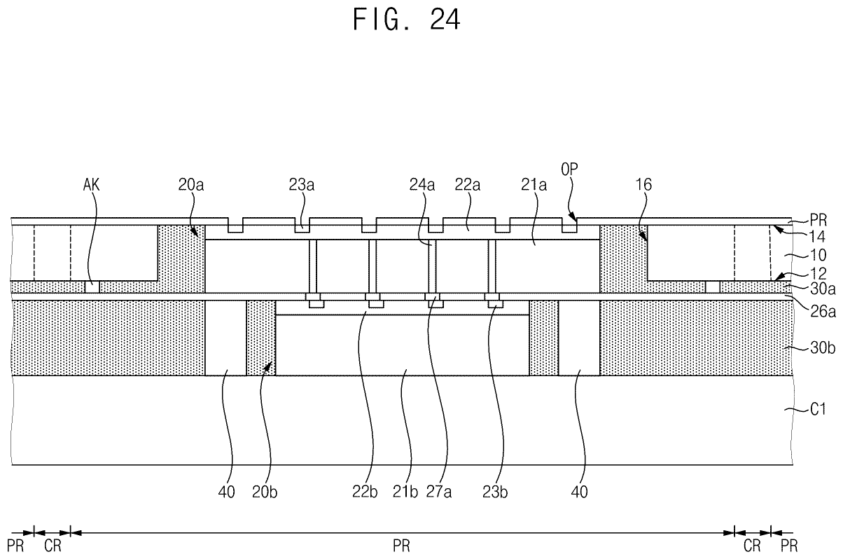

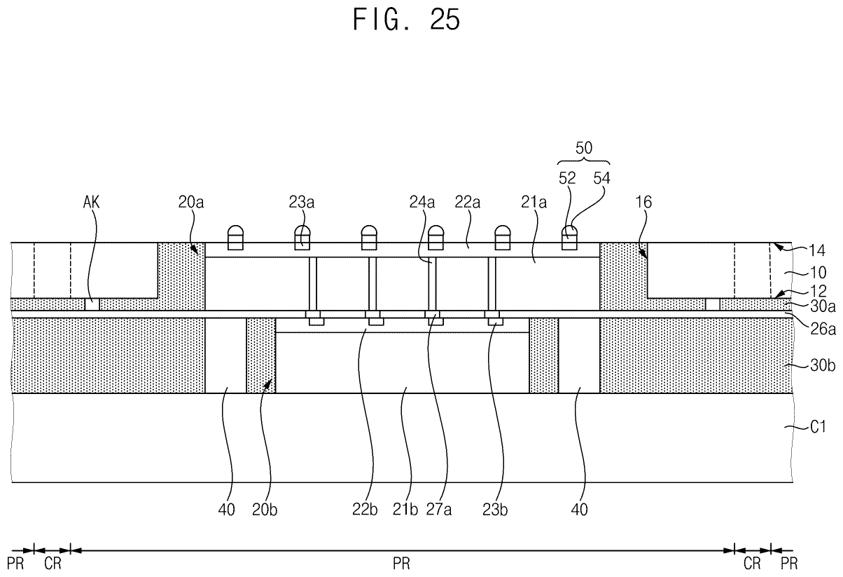

Referring to FIGS. 24 and 25, conductive bumps 50 may be formed on the first bonding pads 23a of the lower semiconductor chip 20a, respectively.

As illustrated in FIG. 24, a seed layer and a photoresist layer may be formed on the first front insulating layer 22a, and an exposure process may be performed to form a photoresist pattern PR having openings OP that expose bump regions.

As illustrated in FIG. 25, after filling the openings OR of the photoresist pattern PR with a conductive material, the photoresist pattern may be removed and a reflow process may be performed to form the conductive bumps 50. Alternatively, the conductive bumps may be formed by a screen printing method, a deposition process, etc.

For example, a pillar bump 52 may be formed on the first bonding pad 23a of the lower semiconductor chip 20a, and a solder bump 54 may be formed on the pillar bump 52.

Then, the support frame GF may be cut along the cutting region CR to form a stacked semiconductor chip 200 (see FIG. 1) as a chiplet package including the first chiplet die 20a and the second chiplet die 20b bonded to each other.

When the support frame GF is cut along the cutting region CR, a portion of the second gap filling layer 30b may be removed together, so that an outer side surface of the second gap filling layer 30b may be coplanar with or located on the same plane as an outer side surface of the glass substrate 10.

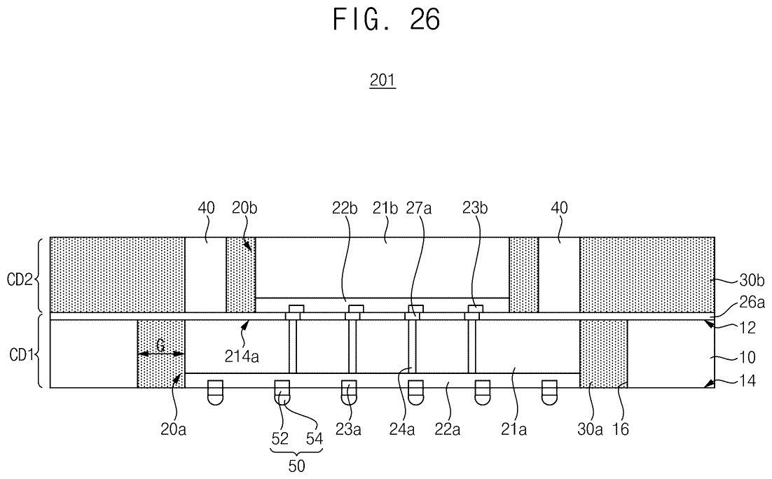

FIG. 26 is a cross-sectional view illustrating a semiconductor device in accordance with example embodiments. The semiconductor device is substantially the same as or similar to the semiconductor device described with reference to FIG. 1 except for arrangement relationship between a glass substrate and a first gap filling layer. Thus, same reference numerals will be used to refer to the same or like elements and any further repetitive explanation concerning the above elements may be omitted in the interest of brevity.

Referring to FIG. 26, a first die structure CD1 as a lower die structure of a semiconductor device, semiconductor packaging device, or semiconductor package 201 may include a support substrate 10 having a cavity 16, a first semiconductor chip 20a disposed in the cavity 16, and a first gap filling layer 30a that fills a gap between an inner wall of the cavity 16 and the first semiconductor chip 20a.

In example embodiments, the first gap filling layer 30a may fill a gap between an outer side surface of the first semiconductor chip 20a and the inner wall of the cavity 16 of the support substrate 10. A first surface 12 of the support substrate 10 may be exposed by the first gap filling layer 30a. The first surface 12 of the support substrate 10 may be coplanar with or located on the same plane as an upper surface of the first gap filling layer 30a. A second surface 14 of the support substrate 10 may be exposed by the first gap filling layer 30a. The second surface 14 of the support substrate 10 may be coplanar with or located on the same plane as a lower surface of the first gap filling layer 30a.

A second surface 214a of a first substrate 21a of the first semiconductor chip 20a may be located on the same plane as the first surface 12 of the support substrate 10. A first backside insulating layer 26a of the first semiconductor chip 20a may extend laterally from the second surface 212a of the first substrate 21a to cover the first gap filling layer 30a and the second surface 12 of the support substrate 10.

A thickness of the support substrate 10 may be the same as a thickness of the first gap filling layer 30a. By increasing a ratio of the support substrate 10 in the first die structure CD1, warpage of the first die structure CD1 may be reduced.

Hereinafter, a method of manufacturing the semiconductor package of FIG. 26 will be described.

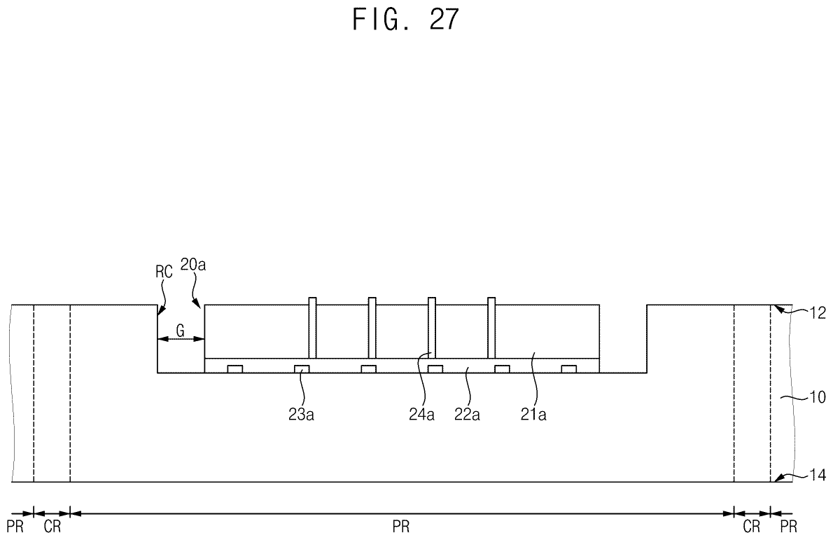

FIGS. 27 to 29 are cross-sectional views illustrating a method of manufacturing a semiconductor device in accordance with example embodiments.

Referring to FIG. 27, processes the same as or similar to the processes described with reference to FIGS. 5 to 11 may be performed to partially remove a backside surface of a lower semiconductor chip 20a that is disposed in a recess RC of a glass substrate 10 to expose an end portion of a through electrode 24a.

In example embodiments, a grinding process such as a back lap process may be performed to partially remove a second surface 214a of a first substrate 21a, and then an etching process such as a silicon recess process may be performed to expose the end portion of the through electrode 24a. Accordingly, a thickness of the first substrate 21a may be reduced to a desired thickness. At this time, the second surface 214a of the first substrate 21a may be positioned on the same plane as the first surface 12 of the glass substrate 10.

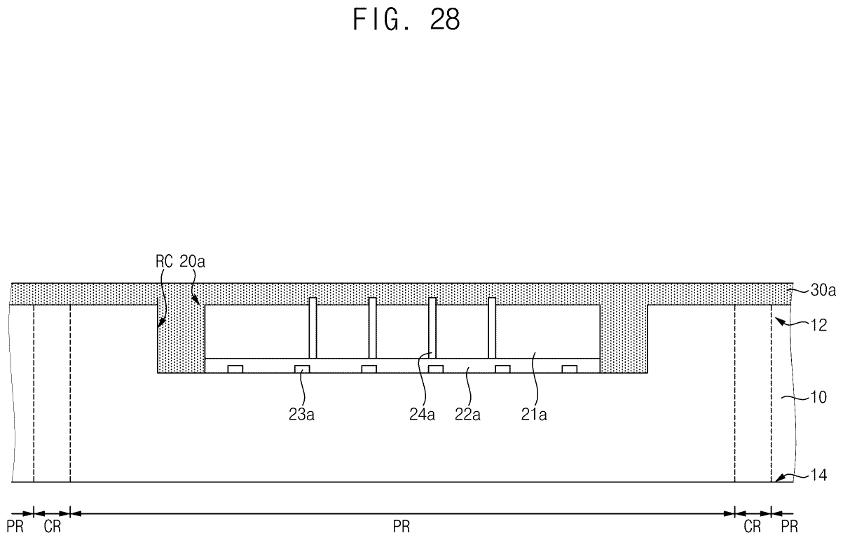

Referring to FIG. 28, a first gap filling layer 30a may be formed on the first surface 12 of a support frame GF to cover the lower semiconductor chip 20a.

In example embodiments, the first gap filling layer 30a may be formed to fill a gap between an outer side surface of the lower semiconductor chip 20a and an inner surface of the recess RC. The first gap filling layer 30a may be formed to cover the first surface 12 of the glass substrate 10. The first gap filling layer 30a may be formed to fill a gap between the protruding end portions of the through electrodes 24a on the second surface 214a of the first substrate 21a. For example, the first gap filling layer 30a may include silicon oxide such as TEOS.

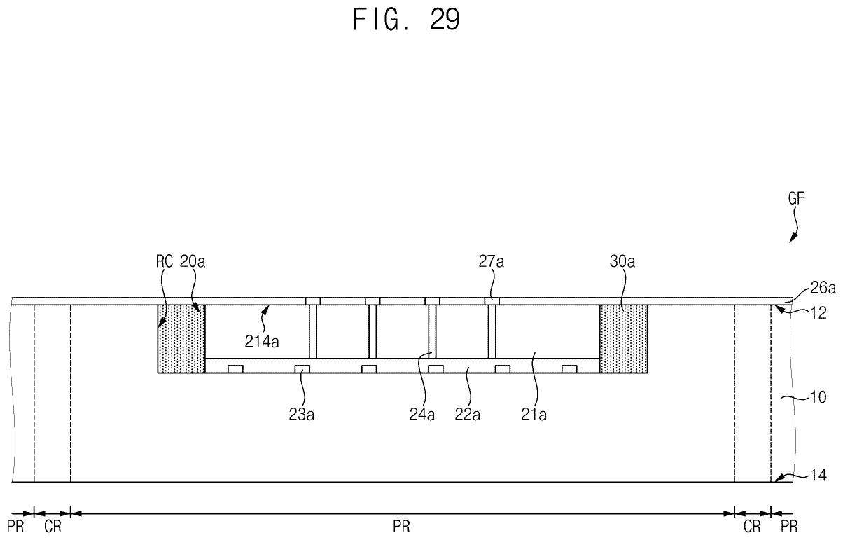

Referring to FIG. 29, processes the same as or similar to the processes described with reference to FIGS. 14 and 15 may be performed to form a first backside insulating layer 26a having second bonding pads 27a therein on the second surface 214a of the first substrate 21a.

First, an upper portion of the first gap filling layer 30a may be removed to expose the end portion of the through electrodes 24a. At this time, the first surface 12 of the glass substrate 10 may be exposed. The first surface 12 of the support substrate 10 may be coplanar with or positioned on the same plane as an upper surface of the first gap filling layer 30a. The second surface 214a of the first substrate 21a of the first semiconductor chip 20a may be coplanar with or positioned on the same plane as the first surface 12 of the support substrate 10.

Then, the first backside insulating layer 26a having the second bonding pad 27a electrically connected to the through electrode 24a may be formed on the second surface 214a of the first substrate 21a. The first backside insulating layer 26a of the first semiconductor chip 20a may extends laterally from the second surface 214a of the first substrate 21a and may extend to cover the first gap filling layer 30a and the first surface 12 of the support substrate 10.

Then, processes the same as or similar to the processes described with reference to FIGS. 16 to 25 may be performed to bond a second semiconductor chip 20b to the first semiconductor chip 20a, to dispose a plurality of dummy chips 40 on the lower semiconductor chip 20a, to partially remove the second surface 14 of the glass substrate 10 to expose the lower semiconductor chip 20a, and to form conductive bumps 50 on the first bonding pads 23a of the lower semiconductor chip 20a.

Then, the support frame GF may be cut along a cutting region CR to form a stack semiconductor chip 201 (see FIG. 26) as a chiplet package including the first semiconductor chip 20a and the second semiconductor chip 20b bonded to each other.

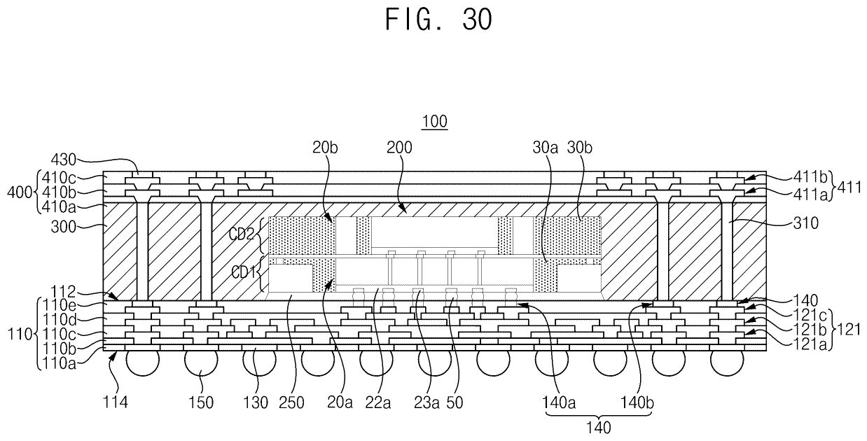

FIG. 30 is a cross-sectional view illustrating a semiconductor package in accordance with example embodiments. The semiconductor package includes the semiconductor device illustrated in FIGS. 1 and 26, however the present inventive concept is not limited thereto.

Referring to FIG. 30, a semiconductor package 100 may include a lower redistribution wiring layer 110, a first semiconductor device 200 disposed on the lower redistribution wiring layer 110, a sealing member 300 on an upper surface of the lower redistribution wiring layer 110 and covering at least a portion of the first semiconductor device 200, and an upper redistribution wiring layer 400 disposed on an upper surface of the sealing member 300. Additionally, the semiconductor package 100 may further include external connection members 150 disposed on an outer or lower surface of the lower redistribution wiring layer 110. The first semiconductor device 200 may be substantially the same as or similar to the semiconductor device described with reference to FIGS. 1 and 26. Thus, same reference numerals will be used to refer to the same or like elements and any further repetitive explanation concerning the above elements may be omitted in the interest of brevity.

In example embodiments, the semiconductor package 100 may be a fan-out package in which the lower redistribution wiring layer 110 extends to the sealing member 300 that covers or surrounds an outer side surface of the first semiconductor device 200. The semiconductor package 100 may be a wafer-level fan-out package or a panel-level fan-out package.

Additionally, the semiconductor package 100 may be provided as a system in package (SIP). The semiconductor package 100 may be provided as a unit package on which a second package is stacked. In this case, the second package may include a second semiconductor device. For example, the first semiconductor device may include a logic chip including a logic circuit, and the second semiconductor device may include a memory chip. The logic chip may be a controller that controls the memory chip. The memory chip may include various types of memory circuits, such as DRAM, SRAM, flash, PRAM, ReRAM, FeRAM, or MRAM.

As illustrated in FIG. 30, the semiconductor package 100 may include the lower redistribution wiring layer 110, the first semiconductor device 200 mounted on the lower redistribution wiring layer 110, vertical conductive structures 310 disposed on the lower redistribution wiring layer 110 and electrically connected to the first semiconductor device 200, a sealing member 300 covering the first semiconductor device 200 on the lower redistribution wiring layer 110 and exposing upper end portions of the vertical conductive structures 310, and the upper redistribution wiring layer 400 on the sealing member 300 and electrically connected to the vertical conductive structures 310.

In example embodiments, the lower redistribution wiring layer 110 may be a front redistribution wiring layer (FRDL) of the fan-out package. The lower redistribution wiring layer 110 may include first to fifth lower insulating layers 110a, 110b, 110c, 110d, and 110e and circuit layers having first redistribution wirings 121 in the lower insulating layers. The first redistribution wirings 121 may include first to third lower redistribution wirings 121a, 121b, and 121c that are vertically stacked.

Lower connection pads 130 may be exposed from a lower surface 114 of the lower redistribution wiring layer 110. Upper connection pads 140 may be exposed from an upper surface 112 of the lower redistribution wiring layer 110. The upper connection pads 140 may include first connection pads 140a disposed in a chip mounting region and second connection pads 140b disposed in a fan-out region surrounding the chip mounting region. The first connection pads 140a may be arranged in an array form within the chip mounting region on the upper surface 112. The lower connection pads 130 may be arranged in an array form over the entire lower surface 114. The upper connection pads 140 and the lower connection pads 130 may be electrically connected to each other through the first redistribution wirings. A data signal, a power signal, or a ground signal may be transmitted through the lower connection pads 130, the first redistribution wirings, and the upper connection pads 140.

The first semiconductor device 200 may be disposed in the chip mounting region, which is a fan-in region of the lower redistribution wiring layer 110. The first semiconductor device 200 may be mounted on the upper surface 112 of the lower redistribution wiring layer 110 using a flip chip bonding method. The first semiconductor device 200 may be arranged such that a first front insulating layer 22a in which first bonding pads 23a are formed faces the lower redistribution wiring layer 110. The first bonding pads 23a of the first semiconductor device 200 may be electrically connected to the first redistribution wirings 121 of the lower redistribution wiring layer 110 through conductive bumps 50. The conductive bumps 50 may be respectively bonded to the first connection pads 140a on the uppermost first redistribution wiring 121c.

Vertical conductive pillars 310 as the vertical conductive structures may respectively extend upward on the second connection pads 140b located in the fan-out region of the lower redistribution wiring layer 110.

The sealing member 300 may at least partially cover the first semiconductor device 200 and the plurality of vertical conductive pillars 310 on the upper surface 112 of the lower redistribution wiring layer 110. The sealing member 300 may expose upper end portions of the vertical conductive pillars 310.

The upper redistribution wiring layer 400 may be disposed on the upper surface of the sealing member 300. The upper redistribution wiring layer 400 may include stacked first to third upper insulating layers 410a, 410b, and 410c and second redistribution wirings 411 in the first to third upper insulating layers 410a, 410b, and 410c. The second redistribution wirings 411 may include first and second upper redistribution wrings 411a and 411b. Upper connection pads 430 may be respectively disposed on the second upper redistribution wrings 411b as the uppermost redistribution wirings.

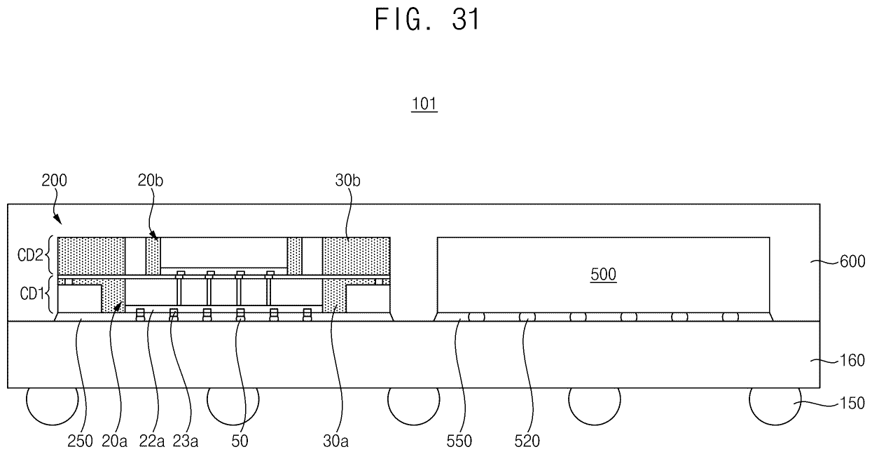

FIG. 31 is a cross-sectional view illustrating a semiconductor package in accordance with example embodiments. The semiconductor package may include the semiconductor device illustrated in FIGS. 1 and 26, however the present inventive concept is not limited thereto.

Referring to FIG. 31, a semiconductor package 101 may include a package substrate 160, a first semiconductor device 200, and a second semiconductor device 500. Additionally, the semiconductor package 101 may further include first and second underfill members 250 and 550 and a sealing member 600. The first semiconductor device 200 may be substantially the same as or similar to the semiconductor device described with reference to FIGS. 1 and 26. Thus, same reference numerals will be used to refer to the same or like elements and any further repetitive explanation concerning the above elements may be omitted in the interest of brevity.

In example embodiments, the semiconductor package 101 may be provided as a portion of a memory module with a 2.5D package structure. In this case, the package substrate 160 may be an interposer for electrically connecting the first and second semiconductor devices 200 and 500 to each other.

In example embodiments, the first semiconductor device 200 may include a logic device, and the second semiconductor device 500 may include a memory device. The logic device may be an application specific integrated circuit (ASIC) chip including, for example, a graphics processing unit (GPU), a central processing unit (CPU), a microprocessor, a microcontroller, an application processor (AP), a digital signal processing core (DSP core), etc. The memory device may include, for example, DRAM, SRAM, flash, PRAM, ReRAM, FeRAM, or MRAM.

In example embodiments, the package substrate 160 may have an upper surface and a lower surface opposite to the upper surface, and may be, for example, a printed circuit board (PCB), a silicon interposer, or a redistribution interposer. The printed circuit board may be a multilayer circuit board having various circuit patterns therein.

The first semiconductor device 200 may be mounted on the package substrate 160. The first semiconductor device 200 may be mounted on an upper surface of the package substrate 160 using a flip chip bonding method. The first semiconductor device 200 may be arranged such that a first front insulating layer 22a in which first bonding pads 23a are formed faces the package substrate 160. The first bonding pads 23a of the first semiconductor device 200 may be electrically connected to substrate pads of the package substrate 160 through conductive bumps 50.

The second semiconductor device 500 may be horizontally spaced apart from the first semiconductor device 200 on the package substrate 160. The second semiconductor device 500 may be mounted on the upper surface of the package substrate 160 via conductive bumps 520.

The first semiconductor device 200 and the second semiconductor device 500 may be electrically connected to each other through wires inside the package substrate 160. The package substrate 160 may provide high-density interconnection between the first and second semiconductor devices 200 and 500.

In example embodiments, the first and second underfill members 250 and 550 may include a material with relatively high fluidity to effectively fill small spaces between the first and second semiconductor devices 200 and 500 and the package substrate 160. For example, the first and second underfill members 250 and 550 may include an adhesive containing an epoxy material.

The sealing member 600 may be provided on the upper surface of the package substrate 160 to cover the first and second semiconductor devices 200 and 500. For example, the sealing member 600 may include an epoxy mold compound (EMC). The sealing member 600 may include UV resin, polyurethane resin, silicone resin, silica fillers, etc.

Although not illustrated in the figure, a heat slug may cover and be in thermal contact with the first and second semiconductor devices 200 and 500 on the package substrate 160. In this case, the sealing member 600 may be omitted. Alternatively, the sealing member 600 may expose upper surfaces of the first and second semiconductor devices 200 and 500, and a heat dissipation member may be disposed on the upper surfaces of the first and second semiconductor devices 200 and 500 exposed by the sealing member 600, and the heat dissipation member may include, for example, a thermal interface material (TIM). The heat slug may be in thermal contact with the first and second semiconductor devices 200 and 500 via the heat dissipation member.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present inventive concept. Accordingly, all such modifications are intended to be included within the scope of example embodiments as defined in the claims.

What is claimed is:

1. A semiconductor device, comprising:
a first die structure including a support substrate having a cavity therein, a first semiconductor chip in the cavity, and a first gap filling layer that fills a gap between an inner wall of the cavity and the first semiconductor chip; and
a second die structure on the first die structure, the second die structure including a second semiconductor chip and a second gap filling layer surrounding an outer side surface of the second semiconductor chip, the second semiconductor chip on the first semiconductor chip and electrically connected to the first semiconductor chip,
wherein the first semiconductor chip includes a first substrate, a first front insulating layer on a first surface of the first substrate with first bonding pads therein or thereon, and a first backside insulating layer on a second surface of the first substrate opposite the first surface of the first substrate with second bonding pads therein or thereon,
wherein the second semiconductor chip includes a second substrate and a second front insulating layer on a first surface of the second substrate with third bonding pads therein or thereon, and
wherein the second bonding pads are directly bonded to the third bonding pads.

2. The semiconductor device of claim 1, wherein the first backside insulating layer is directly bonded to the second front insulating layer.

3. The semiconductor device of claim 1, wherein the support substrate includes a glass substrate.

4. The semiconductor device of claim 1, wherein the first and second gap filling layers include silicon oxide.

5. The semiconductor device of claim 1, wherein the support substrate has a first coefficient of thermal expansion, and the first gap filling layer has a second coefficient of thermal expansion that is greater than the first coefficient of thermal expansion.

6. The semiconductor device of claim 1, wherein a planar area ratio occupied by the support substrate to a total planar area of the first die structure is within a range of 10% to 50%.

7. The semiconductor device of claim 1, wherein the first backside insulating layer laterally extends from the second surface of the first substrate to cover the first gap filling layer.

8. The semiconductor device of claim 1, wherein the first semiconductor chip has a first width and the second semiconductor chip has a second width smaller than the first width.

9. The semiconductor device of claim 1, wherein the second die structure further includes at least one dummy chip adjacent the second semiconductor chip with the second gap filling layer therebetween.

10. The semiconductor device of claim 1, wherein an outer side surface of the second gap filling layer is positioned on a same plane as an outer side surface of the support substrate.

11. A semiconductor device, comprising:
a first die structure including a support substrate including a body having a first surface and a second surface opposite the first surface and having a cavity that extends from the first surface to the second surface with the body surrounding the cavity, a first chiplet die in the cavity, and a first gap filling layer that fills a gap between an inner wall of the cavity and the first chiplet die; and
a second die structure on the first die structure, the second die structure including a second chiplet die on the first chiplet die and electrically connected to the first chiplet die, and a second gap filling layer surrounding an outer side surface of the second chiplet die,
wherein the first chiplet die includes a first substrate, a plurality of through electrodes extending at least partially through the first substrate, first bonding pads on a first surface of the first substrate and electrically connected to the plurality of through electrodes, second bonding pads on a second surface of the first substrate opposite the first surface and electrically connected to the plurality of through electrodes,
wherein the second chiplet die includes a second substrate and third bonding pads on a first surface of the second substrate, and
wherein the first bonding pads are directly bonded to the second bonding pads.

12. The semiconductor device of claim 11, wherein the first chiplet die further comprises a first backside insulating layer on the second surface of the first substrate and exposing at least portions of the second bonding pads,
wherein the second chiplet die further includes a second front insulating layer on the first surface of the second substrate and exposing at least portions of the third bonding pads, and
wherein the first backside insulating layer is directly bonded to the second front insulating layer.

13. The semiconductor device of claim 11, wherein the support substrate includes a glass substrate.

14. The semiconductor device of claim 11, wherein the first and second gap filling layers include silicon oxide.

15. The semiconductor device of claim 11, wherein the support substrate has a first coefficient of thermal expansion, and the first gap filling layer has a second coefficient of thermal expansion that is greater than the first coefficient of thermal expansion.

16. The semiconductor device of claim 11, wherein an area ratio occupied by the support substrate to a total area of the first die structure is within a range of 10% to 50%.

17. The semiconductor device of claim 12, wherein the first backside insulating layer extends laterally from the second surface of the first substrate to cover the first gap filling layer.

18. The semiconductor device of claim 11, wherein the second die structure further includes at least one dummy chip adjacent the second chiplet die.

19. The semiconductor device of claim 11, further comprising:
conductive bumps on the first bonding pads.

20. A semiconductor device, comprising:
a first die structure including a support substrate having a cavity, a first semiconductor chip in the cavity, and a first gap filling layer that fills a gap between an inner wall of the cavity and the first semiconductor chip; and
a second die structure stacked on the first die structure, the second die structure including a second semiconductor chip on the first semiconductor chip and electrically connected to the first semiconductor chip, and a second gap filling layer surrounding the second semiconductor chip,
wherein an outer side surface of the second gap filling layer is coplanar with an outer side surface of the support substrate.
